(19) United States
(12) Patent Application Publication
(10) Pub. No.: US 2016/0315451 A1
(43) Pub. Date: Oct. 27, 2016

(54) Tunable Optical Apparatus

(71) Applicant: Alcatel-Lucent USA Inc., Murray Hill, NJ (US)

(72) Inventors: Guilhem de Valicourt, Jersey City, NJ (US); Po Dong, Morganville, NJ (US)

(73) Assignee: Alcatel-Lucent USA Inc., Murray Hill, NJ (US)

(21) Appl. No.: 15/096,754

(22) Filed: Apr. 12, 2016

Related U.S. Application Data
(60) Provisional application No. 62/151,665, filed on Apr. 23, 2015.

(51) Int. Cl. H01S 5/10; H01S 5/30

(52) U.S. Cl. CPC H01S 5/1096; H01S 5/3013; H01S 5/101

(57) ABSTRACT

A tunable optical apparatus comprises a silicon photonic integrated circuit region and a semiconductor optical amplifier optically coupled to each other. Tuning is achieved by having a first variable optical gate in off-state so as to substantially avoid attenuation of power of a first optical signal propagating through a first optical path and by having a second variable optical gate in on-state so as to attenuate power of a second optical signal propagating through a second optical path, the first optical path and the second optical path being optically coupled to the semiconductor optical amplifier.

This patent application claims the benefit of U.S. provisional patent application No. 62/151665, filed on Apr. 23, 2015, the content of which is herein incorporated by reference in its entirety.

### TECHNICAL FIELD

The present disclosure is directed, in general, to tunable optical apparatus such as for example a tunable laser.

### BACKGROUND

This section introduces aspects that may help facilitate a better understanding of the disclosure. Accordingly, the statements of this section are to be read in this light and are not to be understood as admissions about what is in the prior art or what is not in the prior art.

Wavelength-tunable lasers are an attractive source for use in wavelength division multiplexing (WDM) networks. WDM technologies have been revolutionizing optical core and metropolitan networks and are expected to conquer a large market share in access, datacenter and optical interconnect networks in the near future. However, these segments are particularly sensitive to cost, and therefore footprint and power consumption are matters of concern therein.

Some embodiments feature an apparatus comprising:
a silicon photonic integrated circuit region;
a semiconductor optical amplifier optically coupled to the silicon photonic integrated circuit region;
   wherein the apparatus is configured to have a first variable optical gate in off-state so as to substantially avoid attenuation of power of a first optical signal travelling through a first optical path and by having a second variable optical gate in on-state so as to attenuate power of a second optical signal travelling through a second optical path; and
   wherein the first optical path and the second optical path are optically coupled to the semiconductor optical amplifier.

In some embodiments the silicon photonic integrated circuit region includes the first and the second variable optical gate, one or more first reflectors configured to reflect light in a first direction, a second reflector configured to reflect light in a second direction opposite to the first direction and a multiplexer; and
wherein the first optical path is formed between one of the one or more first reflectors, a first variable optical gate, the multiplexer, the semiconductor optical amplifier and the second reflector, said optical path defining a first laser cavity.

In some embodiments the second optical path is formed between another of the one or more first reflectors, a second variable optical gate, the multiplexer, the semiconductor optical amplifier and the second reflector, said optical path defining a second laser cavity.

In some embodiments the apparatus comprises a phase shifter configured to adjust a phase of an optical signal propagating along an optical path.

In some embodiments the second reflector is abutted against the semiconductor optical amplifier.

In some embodiments the silicon photonic integrated circuit region and the semiconductor optical amplifier form a hybridized structure.

In some embodiments the silicon photonic integrated circuit region and the semiconductor optical amplifier are optically butt-coupled to each other.

In some embodiments the variable optical gates may be variable optical attenuators (VOA), adjustable Mach-Zehnder modulators (MZM), adjustable optical rings or adjustable electro-absorption modulators (EAM).

Some embodiments feature a tunable laser comprising:
a silicon photonic integrated circuit region;
a semiconductor optical amplifier optically coupled to the silicon photonic integrated circuit region;
   wherein the apparatus is configured to have a first variable optical gate in off-state so as to substantially avoid attenuation of power of a first optical signal travelling through a first optical path and by having a second variable optical gate in on-state so as to attenuate power of a second optical signal travelling through a second optical path; and
   wherein the first optical path and the second optical path are optically coupled to the semiconductor optical amplifier.

In some embodiments the silicon photonic integrated circuit region includes the first and the second variable optical gates, one or more first reflectors configured to reflect light in a first direction, a second reflector configured to reflect light in a second direction opposite to the first direction and a multiplexer; and
wherein the first optical path is formed between one of the one or more first reflectors, a first variable optical gate, the multiplexer, the semiconductor optical amplifier and the second reflector, said optical path defining a first laser cavity.

In some embodiments the second optical path is formed between another of the one or more first reflectors, a second variable optical gate, the multiplexer, the semiconductor optical amplifier and the second reflector, said optical path defining a second laser cavity.

In some embodiments, the tunable laser further comprises a phase shifter configured to adjust a phase of an optical signal propagating along an optical path.

In some embodiments, the second reflector is abutted against the semiconductor optical amplifier.

In some embodiments, the silicon photonic integrated circuit region and the semiconductor optical amplifier form a hybridized structure.

### BRIEF DESCRIPTION OF THE DRAWINGS

For a more complete understanding of the present disclosure, reference is now made to the following description taken in conjunction with the accompanying drawings, in which:

FIG. 1 is an exemplary schematic representation of a tunable laser according to known solutions.

FIG. 2 is an exemplary schematic representation of a tunable laser according to known solutions.

FIG. 3 is an exemplary schematic representation of a tunable laser according to some embodiments of the disclosure.

FIG. 4 is an exemplary graphical representation of a transfer function of channels of a wavelength demultiplexer and Fabry-Perot cavity modes of the tunable laser of FIG. 3.

FIG. 5 is an exemplary graphical representation of mode separations for a specific cavity length of the tunable laser of FIG. 3.

### DETAILED DESCRIPTION OF ILLUSTRATIVE EMBODIMENTS

As mentioned above wavelength-tunable lasers are an attractive source for use in wavelength division multiplexing. One cost-effective way to implement tunable lasers is to integrate the sources and the wavelength multiplexer into the same chip. In such approach, the wavelength multiplexer also acts as intracavity filter and therefore determines the lasing wavelength. Such lasers may be used as a simple wavelength selectable source. The laser wavelength can be switched to any of the AWG channels. Compared to a fully tunable laser, this switching technique is simpler and faster.

Optical packet switching in optical communications is well-known in the related art. Such technique has introduced certain new requirements on fast tunable lasers such that said lasers are capable of changing their emission wavelength on a per-slot basis and be used as local oscillators to enable coherent optical receivers to become fast wavelength-tunable. Coherent optical receivers are typically able to select one of the wavelengths from a comb of wavelengths received without the need of optical filtering. This selection capability is possible because while the local oscillator of the receiver is typically tuned to the wavelength it is configured to select, it is not tuned to the neighboring channels and therefore optical beat frequencies are generated between the neighboring channels and the local oscillator which are detectable and can be removed by appropriate low-pass analog filtering using photodiodes (PDs) and analog-to-digital converters (ADCs) or any other filtering technique by digital signal processing. This “colorless” capability of the coherent receiver allows any node of an optical network to receive optical channels from any other node by rapidly tuning the wavelength of the local oscillator to the optical channel which is desired to be detected. This implies that the tuning of the laser needs to be fast because during the tuning time data cannot be transmitted or received. In the context of the present disclosure a switching speed of 30 ns may be considered as sufficiently fast so as to guarantee the optical packet integrity.

To obtain a fast tunable laser one known solution relates to the use of a filter based on an arrayed waveguide grating (AWG) in the laser. In this arrangement the AWG filter is incorporated in the laser cavity which is made using an Indium-Phosphate (InP) platform.

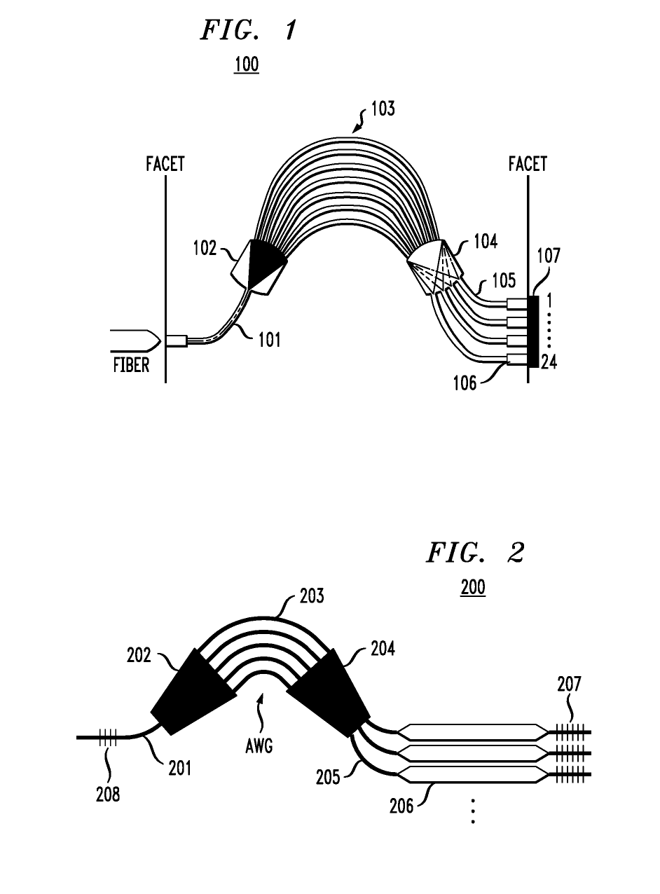

FIG. 1 is a schematic representation of a known AWG-laser 100. The AWG 100 comprises an input waveguide 101 which is coupled to a first free space region 102 which in turn is coupled to a plurality of intermediate waveguides generally shown by reference numeral 103. The plurality of waveguides 103 are coupled to a second free space region 104. The second free space region 104 is coupled to a plurality of output waveguides 105 that are coupled at their respective opposite ends to respective semiconductor optical amplifiers (SOA) generally represented by reference numeral 106. The SOA array 106 is coupled to a mirror facet 107. A second mirror facet arrangement 108 is provided at the input side to configure the laser cavity of the overall device.

By way of a brief description of the operation of the device, a multi-wavelength optical signal may be injected into the input waveguide 101 of the AWG. As it is know, upon propagating through the first free space region 102, the waveguide grating 103 and the second free space region 104, individual wavelengths are output from the latter into respective output waveguides 105. The individual wavelengths then reach the respective SOAs 106 where they are amplified and reflected back by the effect of the mirror fact 107. According to this known solution, each SOA may be turned on in order to emit one wavelength, or turned off in order to avoid emission of the respective wavelength. Such configuration therefore allows for providing a multi-frequency laser by emitting several wavelengths at the same time. However the integration of the various components of the laser in the InP platform typically results in a large footprint (e.g. 18 cm×9 mm). In addition to the relatively large size of the resulting device, which is typically not desirable, certain other drawbacks are also associated with this design. For example the large size also implies high manufacturing cost as InP materials are typically more expensive than silicon materials. Furthermore, a long Fabry-Perot cavity typically induces closer longitudinal modes (as described in further detail below) which would make mode selection more difficult.

An alternative known solution relates to the use of silicon photonics which has been viewed as a promising candidate for producing such devices because it allows high-density integration and production with the benefit of large-scale manufacturing. This photonic technology in a complementary metal-oxide-semiconductor (CMOS) platform can typically allow the production of low cost and compact circuits that integrate photonic and microelectronic elements. However, in the known silicon photonic structures light emission and amplification is typically not available. In this regard, some recent works have proposed an optically pumped germanium laser, however practical applications do not appear to be satisfactory at present time.

Further research work has focused on the rather complex heterogeneous integration of III-V semiconductors on silicon. Such hybrid integration has been proposed in the literature in order to incorporate III-V photonic functionality on the Silicon-on-Insulator (SOI) platform by means of molecular wafer bonding to take advantage of the properties of both the photonic InP material and the silicon platforms. Hybrid silicon devices have the optical properties of the III-V material, such as gain (emission or amplification), high-speed modulation, and photodetection, while still being located on an SOI circuit.

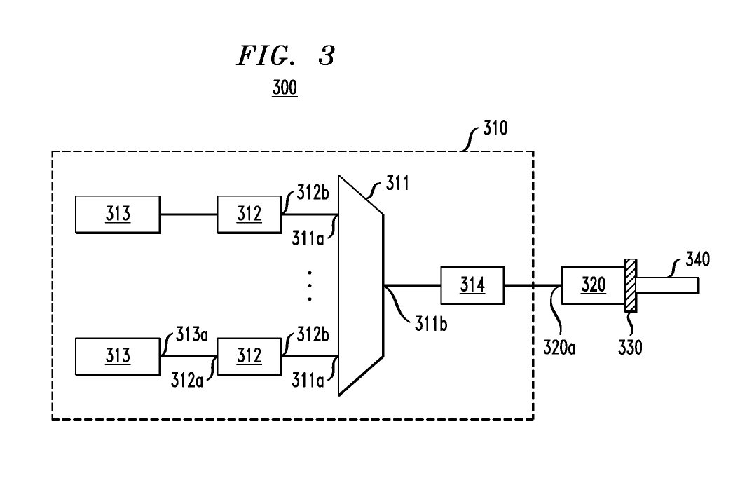

A schematic view of the above approach is provided in FIG. 2. In FIG. 2, like elements have been given the last two digits of like elements in FIG. 1. The reflective functionalities in the laser 200 of FIG. 2 are provided by Bragg reflectors. The operational concept of the laser 200 shown in FIG. 2 is similar to the one presented above with reference to FIG. 1 and therefore a detailed description thereof is considered not necessary. However, differently from FIG. 1, in the laser 200 of FIG. 2 the gain sections 206 are in III-V material and the AWG (201, 202, 203, 204, 206), the reflectors 207 and 208 and any required couplers are in silicon. In this approach, similar to the arrangement of FIG. 1, one SOA per channel is required in order to provide tunability.

However, the use of one SOA per channel induces reliability problems. Furthermore, compatibility with CMOS technology is reduced and in practice a commercial foundry may be reluctant to use both materials in the same platform.

Embodiments of the present disclosure address the above problems and propose a solution for providing fast tunable lasers which overcomes or substantially reduces the drawbacks associated with the known techniques.

The present disclosure allows for developing a low cost digitally tunable laser by integrating a wavelength multiplexer, one or more variable optical gates and at least two reflectors into a silicon photonic integrated circuit which is coupled to an SOA as will be described below.

FIG. 3 shows an exemplary schematic representation of a tunable laser 300 according to some embodiments. The tunable laser 300 comprises a silicon photonic integrated circuit (SPIC) region 310 which is highlighted in FIG. 3 by a dashed rectangle and a SOI 320 which may be made using III-V material.

The SPIC region 301 comprises a wavelength multiplexer/demultiplexer 311 (herein referred to as “multiplexer” for simplicity), an array of variable (or adjustable) optical gates generally shown by reference numeral 312 and an array of first optical reflectors such as mirrors generally shown by reference numeral 313. The SPIC 301 may preferably further comprise a phase shifter 314 to ensure mode stability.

Each variable optical gate 312i from the array of optical gates 312 is optically coupled at a first port thereof 312ai to an output 313ai of a respective first optical reflector 313i from the first optical reflector array 313; and is further optically coupled at a second port thereof 312bi to an input 311ai of the multiplexer 311. Herein, i is a positive integer such that 1≦i≦M where M is the total number of variable optical gates 312.

An output 311b of the demultiplexer 311 is optically coupled to an input port of the phase shifter 314 which in turn has an output optically coupled to an optical port 320a of the SOA 320.

Variable optical gates 312 may be variable optical attenuators (VOA), adjustable Mach-Zehnder modulators, adjustable optical rings or adjustable electro-absorption modulators (EAM). In the following description, the use of VOAs is disclosed as an example of a suitable variable optical gate. However, the disclosure is not so limited and other examples of variable optical gates, for example, the ones mentioned above may also be used without departing from the scope of the present disclosure.

Multiplexer 311 may be of any known type such as for example AWG, echelle grating, optical rings.

Reflectors 313 and 330 may be of any know type such as for example Bragg reflectors, Sagnac loop mirrors or the like.

Preferably all connections are made by waveguides. However different types of waveguides as known by those skilled in the related art may be used.

At a side opposite to the side where the optical port 320a is located, the SOA 320 is coupled to a second optical reflector 330, such as a mirror. The second optical reflector 330 may be partially reflective (or said in a different way, partially transparent).

In the above-described arrangement, light may be made to travel back and forth between a first optical reflector 331i from the first optical reflector array 313 and the second optical reflector 330 and amplified in the SOA 320 at each travelling direction until such amplification surpasses a lasing power threshold that causes the light to pass through, or lase out from, the second mirror 340 where it may be input into the optical media to which it is intended to input light, such as an optical fiber.

Therefore, a laser cavity of the Fabry-Perot (FP) type is formed between the first optical reflector 313i and the second optical reflector 330 where the laser cavity length is the optical path defined by the trajectory through which light travels between the first optical reflector 313i and the second optical reflector 340.

In order to tune the laser to a specific wavelength, use is made of the VOAs 312. VOAs are known to attenuate the power of the light propagating therethrough to any desirable level of up to 30-40 dB. Therefore, in order to allow a specific wavelength to be amplified in the laser 300, the VOA which corresponds to the path through which that wavelength is travelling may be turned off (thus no attenuation of light power), and the VOAs corresponding to the paths through which the rest of the wavelengths are travelling may be turned on (thus attenuating the respective light power). This operation tunes the laser 300 to the specific wavelength which is desired for transmission.

In operation, individual wavelengths propagate through respective optical paths of the laser 300. Each individual optical path comprises a first reflector 313i and a respective VOA 312i. Assuming that the laser needs to be tuned to an individual wavelength k (1≦k≦M), VOA 312k is turned off and all the rest of the VOAs from the array of VOAs 312 are turned on. As a result wavelength k is enabled to travel back and forth between the first reflector 313k and the second reflector 330 and is amplified each time it travels through the SOA 320 in the forward and the backward directions. Once the amplification of the wavelength k surpasses the lasing power threshold wavelength k passes through the second mirror 340 and is transmitted by the laser 300.

One possible approach for the hybridization of the SPIC 310 and the SOA 320 may be by employing butt coupling. Other known approaches may also be employed such as for example bonding of III-V dies or wafers onto a processed Si wafer, using electrically pumped highly strained and heavily doped Ge materials or using of III-V on Si hetero-epitaxy.

In the known solutions, where an array of SOAs is used, an efficient alignment may become complex because all the SOAs need to be aligned with precision.

In contrast, the present disclosure relates to a tunable laser which, in its broadest aspect, does not need to use more than one SOA chip and one silicon-based photonic integrated circuit, thus making the alignment task much simpler. The VOAs may be all integrated into the SPIC and not in the SOA chip.

A further advantage of the solution proposed herein is that the III-V chip (for the SOA) and the silicon chip (for the SPIC) may be fabricated separately, thereby enabling fabrication through current commercial foundry and maintaining compatibility with CMOS technology. Each one of the two chips may be optimized separately.

As non-limiting examples, the first reflectors 313i may present 100% reflectivity and the second reflector 330 may present 30% of reflectivity. Other values, known to those of skill in the related art may also be used according to the requirement of each specific design.

The SOA may be butt-coupled or directly integrated via wafer bonding with the second mirror which is made in the SPIC region.

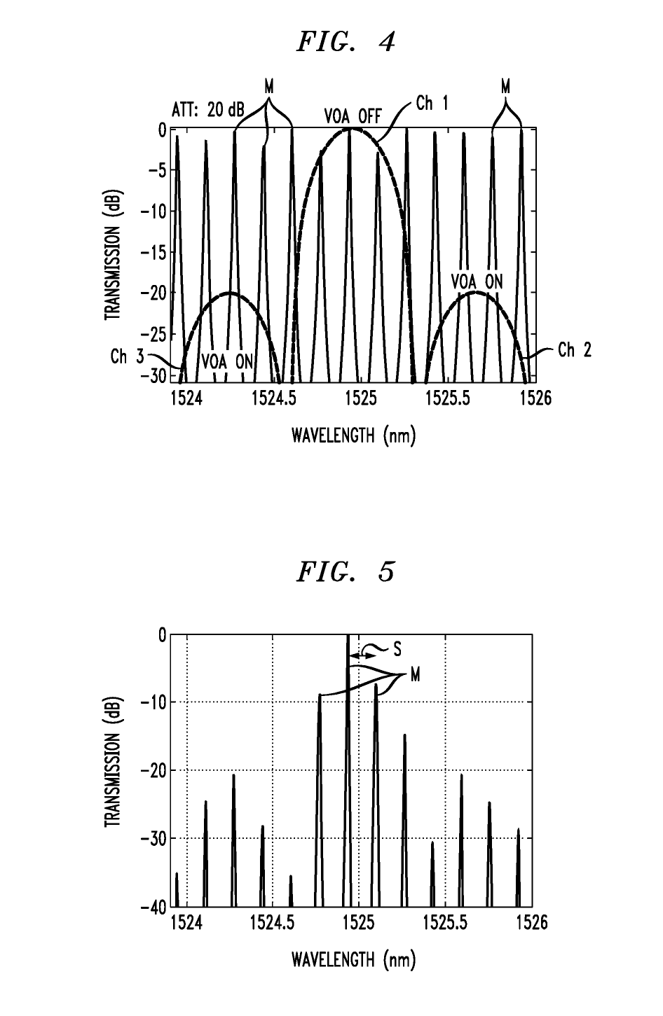

An exemplary transfer function of the wavelength demultiplexer channel and the FP cavity modes is represented in FIG. 4. As explained previously the transmission of each channel can be turned on and off using the VOA devices 312. In FIG. 4, the transfer function of a 100 Ghz channel spacing multiplexer is presented as Ch1, Ch2 and Ch3 (only 3 channels are shown) and the Fabry-Perot longitudinal modes are generally represented as FPM. The corresponding VOA of the central channel Ch1 is turned off so no attenuation is applied thereto. The VOAs of the side channels Ch2 and Ch3 are turned on, so these channels are attenuated. In this example, a 20 dB attenuation is applied to channels Ch2 and Ch3, thereby causing only the FP mode inside the central channel Ch1 to lase.

However, as can be seen in FIG. 4, channel Ch1 includes more than one mode FPM while it is desirable to configure the FP cavity specifically for a single mode operation when only one channel is turned on, i.e. Ch1 in this example.

In order to address the above matter, the FP modes positions relative to the wavelength multiplexer channel and the separation between the FP modes need to be adjusted.

The positions of the modes FPM relative to the wavelength multiplexer channel Ch1, may be controlled using the phase shifter 314. Adjustments applied to the phase shifter therefore may change the position of the modes FPM as desired. As shown in FIGS. 4 and 5, multi-FP modes are inside each channel however only one channel is lasing (the one with lower attenuation). The phase shifter 314 is used to ensure that one of the FP modes is well aligned with the maximum transmission of the AWG channel (with the respective attenuator switched OFF).

The separation between the modes FPM may be controlled by the FP cavity length. Indeed, a shorter cavity may induce more separation between FP modes as compared to a longer cavity. In FIG. 5, exemplary simulations for a 3 mm cavity are shown. In this example, 3 FP modes are shown to be inside one channel. By adjusting the relative position of the FP modes using the phase shifter as described above, a difference of 7 dB between the principal mode and the secondary mode is observed in this example. Such difference can, for example, be increased by reducing the cavity length. In a practical implementation, a minimum cavity length may be determined based on the physical size of the devices.

In some embodiments the hybrid integrated tunable laser as proposed herein may comprise a reflective semiconductor optical amplifier (RSOA) having a mirror deposited on the facet of the SOA. The RSOA may be butt-jointed with a Silicon based photonic integrated circuit as a wavelength-tunable filter. The fabrication of the Si waveguides and the VOA elements may be carried out using known techniques. The VOAs may be p-i-n junctions based on carrier injection. The VOA corresponding to a respective channel may be forward-biased in order to increase the propagation loss (i.e. attenuation) due to the variation of carrier concentration.

As already mentioned above, the Fabry-Perot cavity may be closed using a 100% reflection mirror which may by using a Sagnac loop mirror which includes one 1×2 MMI and one waveguide loop. The 30% reflector is the facet of the RSOA (cleaved facet). On the output side of the SPIC chip, an inverted taper may be used in order to couple the light to the SOA device.

Fast switching between the channels is obtained by switching on and off the VOA devices. Therefore the switching speed of the laser depends on the switching speed of the VOAs. In a practical experiment, a 10%-90% rise/fall time was shown to be less than 10 ns. A switching time of less than 30 ns is well below typical slot duration of a few μs and is sufficient for packet-switching operations.

The proposed solution has many advantages as it provides a compact and low cost tunable laser based on hybrid integration. Compared to other heterogeneous integrated devices based on wafer bonding, the proposed approach increases the compatibility with CMOS technology as the Silicon PIC and the III-V SOA can be optimized and fabricated separately and hybridized later.

Another advantage is that in the present solution may only one SOA may be needed, thereby contributing to cost reduction (although the use of more than SOA is not excluded). Typically III-V material is more expensive than silicon. As the percentage of III-V compared to silicon materials in the proposed design is reduced and all complex elements are placed in the silicon chip, significant cost reduction may be achieved. Furthermore, in the hybridization process of the proposed device only one alignment is needed between the SPIC chip and the SOA.

While this disclosure includes references to illustrative embodiments, this specification is not intended to be construed in a limiting sense. Various modifications of the described embodiments, as well as other embodiments within the scope of the disclosure, which are apparent to persons skilled in the art to which the disclosure pertains are deemed to lie within the principle and scope of the disclosure, e.g., as expressed in the following claims.

Unless explicitly stated otherwise, each numerical value and range should be interpreted as being approximate as if the word “about” or “approximately” preceded the value or range.

Reference herein to “one embodiment” or “an embodiment” means that a particular feature, structure, or characteristic described in connection with the embodiment can be included in at least one embodiment of the disclosure. The appearances of the phrase “in one embodiment” in various places in the specification are not necessarily all referring to the same embodiment, nor are separate or alternative embodiments necessarily mutually exclusive of other embodiments. The same applies to the term “implementation.”

Also for purposes of this description, the terms “couple,” “coupling,” “coupled,” “connect,” “connecting,” or “connected” refer to any manner known in the art or later developed in which energy is allowed to be transferred between two or more elements, and the interposition of one or more additional elements is contemplated, although not required. Conversely, the terms “directly coupled,” “directly connected,” etc., imply the absence of such additional elements.

The described embodiments are to be considered in all respects as only illustrative and not restrictive. In particular, the scope of the disclosure is indicated by the appended claims rather than by the description and figures herein. All changes that come within the meaning and range of equivalency of the claims are to be embraced within their scope.

The contents of the following references are incorporated herein in their entirety.

M. Zirngibl, C. H. Joyner, C. R. Doerr, L. W. Stultz, and H. M. Presby, “An 18-channel multifrequency laser,” Photon. Technol. Lett., Vol. 8, no. 7, p. 870, July 1996.

Y. pointurier et al., “High Data Rate Coherent Optical Slot Switched Networks: a Practical and Technological Perspective,” Com. Mag, to be published.

Camacho-Aguilera, R. E.; et al., “Germanium laser: A CMOS compatible light emitter,” Group IV Photonics (GFP), 2012 IEEE 9th International Conference on, vol., no., pp. 323, 324, 29-31 Aug. 2012A.

G. Kurczveil et al., “An Integrated Hybrid Silicon Multiwavelength AWG Laser,” JSTQE, Vol. 17, No. 6 (2011).

A. Le Liepvre et al., “Wavelength Selectable Hybrid III-V/Si Laser Fabricated by Wafer Bonding,” Photon. Technol. Lett., Vol. 25, no. 5, p. 1582 (2013).

S. Keyvaninia et al., “Heterogeneously integrated III-V/Si multi-wavelength laser based on a ring resonator array multiplexer,” Proc. ACP, AF4A (postdeadline), Guangzhou (2012).

Kenji Sato et al,. “High Output Power and Narrow Linewidth Silicon Photonic Hybrid Ring-Filter External Cavity Wavelength Tunable Lasers”, Proceeding of ECOC, PD2.3 (post-deadline), Cannes, France, 2014.

G. de Valicourt et al., “High Gain (30 dB) and High Saturation Power (11 dBm) RSOA Devices as Colourless ONU Sources in Long Reach Hybrid WDM/TDM-PON Architecture”, Photon. Technol. Lett., Vol. 22, No. 3, p. 191 (2010).

G. de Valicourt et al., “Monolithic integrated silicon-based slot-blocker for packet-switched networks”, in Proc. ECOC' 14, We.3.5.5 (2014).

Y. Urino, et al., “First demonstration of high density optical interconnects integrated with lasers, optical modulators, and photodetectors on single silicon substrate”, Opt. Express, vol. 19, No 26 2011.

A. W. Fang, et al., “Electrically pumped hybrid AlGaInAs-silicon evanescent laser”, Opt. Express, vol. 14, No 20, 2006

J. F. Liu, et al., “A Ge-on-Si laser operating at room temperature”, Optics Lett., vol. 35, pp. 679-681, March 2010.

A. Y. Liu, et al., “High performance continuous wave 1.3 μm quantum dot lasers on silicon”, Applied Physics Letters, Volume: 104 Issue: 4 Pages: 041104.1-041104.4, Jan. 28, 2014.

What is claimed is:

1. An apparatus comprising:
a silicon photonic integrated circuit region;
a semiconductor optical amplifier optically coupled to the silicon photonic integrated circuit region;
wherein the apparatus is configured to have a first variable optical gate in off-state so as to substantially avoid attenuation of power of a first optical signal travelling through a first optical path and by having a second variable optical gate in on-state so as to attenuate power of a second optical signal travelling through a second optical path; and
wherein the first optical path and the second optical path are optically coupled to the semiconductor optical amplifier.

2. The apparatus of claim 1, wherein the silicon photonic integrated circuit region includes the first and the second variable optical gates, one or more first reflectors configured to reflect light in a first direction, a second reflector configured to reflect light in a second direction opposite to the first direction and a multiplexer; and
wherein the first optical path is formed between one of the one or more first reflectors, a first variable optical gate, the multiplexer, the semiconductor optical amplifier and the second reflector, said optical path defining a first laser cavity.

3. The apparatus of claim 2, wherein the second optical path is formed between another of the one or more first reflectors, a second variable optical gate, the multiplexer, the semiconductor optical amplifier and the second reflector, said optical path defining a second laser cavity

4. The apparatus of claim 1 further comprising a phase shifter configured to adjust a phase of an optical signal propagating along an optical path.

5. The apparatus of claim 1, wherein the second reflector is abutted against the semiconductor optical amplifier.

6. The apparatus of claim 1, wherein the silicon photonic integrated circuit region and the semiconductor optical amplifier form a hybridized structure.

7. The apparatus of claim 6, wherein the silicon photonic integrated circuit region and the semiconductor optical amplifier are optically butt-coupled to each other.

8. The apparatus of claim 1, wherein the first and the second variable optical gates are variable optical attenuators, adjustable Mach-Zehnder modulators, adjustable optical rings or adjustable electro-absorption modulators.

9. A tunable laser comprising:
a silicon photonic integrated circuit region;
a semiconductor optical amplifier optically coupled to the silicon photonic integrated circuit region;
wherein the apparatus is configured to have a first variable optical gate in off-state so as to substantially avoid attenuation of power of a first optical signal travelling through a first optical path and by having a second variable optical gate in on-state so as to attenuate power of a second optical signal travelling through a second optical path; and
wherein the first optical path and the second optical path are optically coupled to the semiconductor optical amplifier.

10. The tunable laser of claim 9, wherein the silicon photonic integrated circuit region includes the first and the second variable optical gates, one or more first reflectors configured to reflect light in a first direction, a second reflector configured to reflect light in a second direction opposite to the first direction and a multiplexer; and
wherein the first optical path is formed between one of the one or more first reflectors, a first variable optical gate, the multiplexer, the semiconductor optical amplifier and the second reflector, said optical path defining a first laser cavity.

11. The apparatus of claim 10, wherein the second optical path is formed between another of the one or more first reflectors, a second variable optical gate, the multiplexer, the semiconductor optical amplifier and the second reflector, said optical path defining a second laser cavity.

12. The tunable laser of claim 9 further comprising a phase shifter configured to adjust a phase of an optical signal propagating along an optical path.

13. The tunable laser of claim 9, wherein the second reflector is abutted against the semiconductor optical amplifier.

14. The tunable laser of claim 9, wherein the silicon photonic integrated circuit region and the semiconductor optical amplifier form a hybridized structure.
